(19) United States
(12) Patent Application Publication
(10) Pub. No.: US 2007/0126430 A1
(43) Pub. Date: Jun. 7, 2007

(54) System and method for testing power durability of saw filter

(75) Inventors: Young-Goo Kim, Chungbuk (KR); Jong-Jun You, Daejon (KR); Hong-Joo Kim, Daejon (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Electronics and Telecommunications Research Institute

(21) Appl. No.: 11/605,507

(22) Filed: Nov. 28, 2006

(30) Foreign Application Priority Data
Dec. 1, 2005 (KR) 10-2005-0116096
Jul. 31, 2006 (KR) 10-2006-0072401

(51) Int. Cl. G01R 31/02

(52) U.S. Cl. 324/537

(57) ABSTRACT

A system for testing a power durability of a SAW filter includes: a signal generator for generating a continuous wave of an oscillator; a high power amplifier for amplifying a signal applied from the signal generator into a target power level; a power durability tester (PDT) for receiving the amplified signal from the high power amplifier and monitoring a power applied to a SAW filter, and setting a path for monitoring an electrical property through a network analyzer; a power meter for measuring an output signal of the PDT; a controller for changing a path to monitor an electric property of the PDT; the network analyzer for analyzing an electrical property of the SAW filter; a reliability tester for applying a test temperature to the SAW filter and maintaining the applied test temperature; a thermal meter for measuring a temperature of the SAW filter; a temperature controller for controlling a test temperature applied to the reliability tester; and a computer for controlling the signal generator, the power meter, the network analyzer, the controller, the temperature controller, and the thermal meter.

### FIELD OF THE INVENTION

The present invention relates to system and method for testing a power durability of a surface acoustic wave (SAW) filter, which can perform a reliable accelerated life test of the SAW filter.

### DESCRIPTION OF RELATED ART

With the development of mobile communication and semiconductor technology, semiconductor parts, especially RF device and components, become small-sized and highly integrated. Thus, the reliability is required in order to increase the competitive power for products of other companies or foreign products and to reduce enormous time, equipment and expense necessary for development, production, and test.

An accelerated life reliability test is performed to develop a new semiconductor test sample with high reliability and is necessary to predict the life span of semiconductor devices and parts. Specifically, the accelerated life reliability test using a power durability test method is essential to estimate the life span of a surface mounted device (SMD) type SAW filter and an SAW duplexer, which are used in a mobile terminal.

The accelerated life reliability test is widely used in SAW filters, cellular phones, RF circuits, and so on.

In the case of the cellular phone, an SAW antenna duplexer is an important device to downsize a system. The SAW antenna duplexer includes a reception SAW filter and a transmission SAW filter. In order for the miniaturization, increase of the reception sensitivity, and stability of transmission power, high isolation is required to provide low insertion loss and suppress a mutual interference in transmission and reception. In addition, the SAW antenna duplexer must have high power characteristic.

The SAW antenna duplexer must receive a high power signal applied from a pulse amplitude modulation (PAM). In this case, the high power signal causes a migration phenomenon due to heat inside a device, thus damaging an InterDigital transducer (IDT).

A conventional power durability test method is disclosed in U.S. Pat. No. 6,407,486 B1, entitled “SURFACE ACOUSTIC WAVE DEVICE.” This patent, however, has a problem in that it cannot provide convenience and reliability.

### SUMMARY OF THE INVENTION

It is, therefore, an object of the present invention to provide a system and method for testing a power durability of a SAW filter, which can predict the life span of an SAW device and a filter through a reliable power durability test. In addition, the system and method of the present invention can correctly maintain the temperature such that the acceleration condition of the accelerated life test is satisfied. When a failure condition is satisfied, time, temperature, and change in electrical property can be correctly checked. By applying an accelerated life model, the life span can be predicted in an optimal condition. Therefore, failure can be analyzed.

In accordance with an aspect of the present invention, there is provided a system for testing a power durability of a SAW filter, including: a signal generator for generating a continuous wave of an oscillator; a high power amplifier for amplifying a signal applied from the signal generator into a target power level; a power durability tester (PDT) for receiving the amplified signal from the high power amplifier and monitoring a power applied to a SAW filter, and setting a path for monitoring an electrical property through a network analyzer; a power meter for measuring an output signal of the PDT; a controller for changing a path to monitor an electric property of the PDT; the network analyzer for analyzing an electrical property of the SAW filter; a reliability tester for applying a test temperature to the SAW filter and maintaining the applied test temperature; a thermal meter for measuring a temperature of the SAW filter; a temperature controller for controlling a test temperature applied to the reliability tester; and a computer for controlling the signal generator, the power meter, the network analyzer, the controller, the temperature controller, and the thermal meter.

In accordance with another aspect of the present invention, there is provided a method for testing a power durability of a SAW filter, including the steps of: controlling first and second switches to measure an electrical property of the SAW filter using a network analyzer before test; controlling the first and second switches to applying a high-power continuous wave signal to the SAW filter; measuring a test power of the continuous wave and an output power of the SAW filter using a power meter; when the test power and the output power deviate from a failure criterion, automatically interrupting the continuous wave signal from the signal generator and finishing the test; and measuring the electrical properties of the SAW filter after the test through the network analyzer by using the first and second switches.

### BRIEF DESCRIPTION OF THE DRAWINGS

The above and other objects and features of the present invention will become apparent from the following description of the preferred embodiments given in conjunction with the accompanying drawings, in which:

FIG. 1 is a block diagram of a system for testing a power durability of a SAW filter in accordance with an embodiment of the present invention;

FIG. 2 is a perspective view of a reliability tester of FIG. 1; and

FIG. 3 is a flowchart illustrating a method for testing a power durability of a SAW filter in accordance with an embodiment of the present invention.

### DETAILED DESCRIPTION OF THE INVENTION

Other objects and aspects of the invention will become apparent from the following description of the embodiments with reference to the accompanying drawings, which is set forth hereinafter.

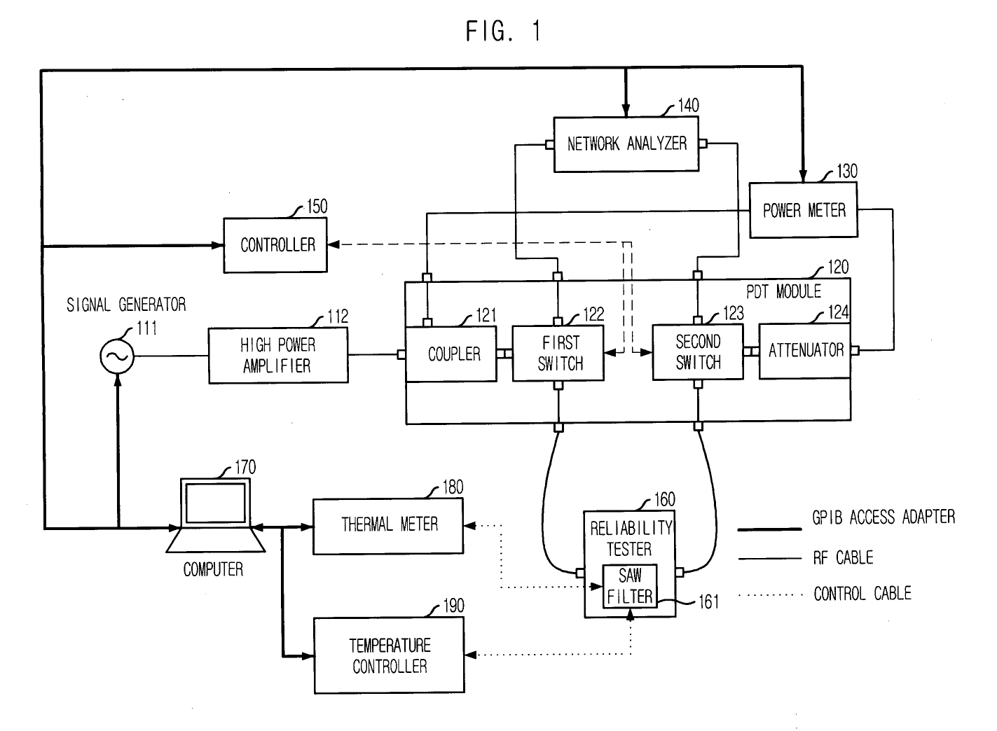

FIG. 1 is a block diagram of a system for testing a power durability of a SAW filter in accordance with an embodiment of the present invention.

Referring to FIG. 1, the system in accordance with the present invention includes a signal generator 111, a high power amplifier 112, a power durability tester (PDT) module 120, a power meter 130, a network analyzer 140, a controller 150, a reliability tester 160, a thermal meter 180, a temperature controller 190, and a computer 170. The signal generator 111 generates a continuous wave (CW) of an oscillator, and the high power amplifier 112 amplifies a signal applied from the signal generator 111 to a target power level to be measured. The PDT module 120 receives the amplified signal from the high power amplifier 112 and monitors a power applied to the SAW filter 161, and sets a path for monitoring an electrical property using the network analyzer 140. The power meter 130 measures an output signal of the PDT module 120, and the controller 150 changes the path so as to monitor an electrical property of the PDT module 120. The network analyzer 140 analyzes an electrical property of the SAW filter 161. The reliability tester 160 applies a test temperature to the SAW filter 161 and maintains the applied test temperature, and the thermal meter 180 measures a temperature of the SAW filter 161. The temperature controller 190 controls the test temperature applied to the reliability tester 160. The computer 170 controls the signal generator 111, the power meter 130, the network analyzer 140, the controller 150, the temperature controller 190, and the thermal meter 180.

The PDT module 120 includes a coupler 121, first and second RF switches 122 and 123, and an attenuator 124. The coupler 121 monitors the power applied to the SAW filter 161, and the first and second RF switches 122 and 123 changes the path to monitor the electrical property of the SAW filter 161 using the network analyzer 140. The attenuator 124 attenuates a power level such that the test power level applied to the power meter 130 can be measured by the power meter 130. Also, the attenuator 124 protects the power meter.

The CW signal of the oscillator, which is generated from the signal generator 111, is inputted to the high power amplifier 112. At this point, the frequency and power level of the signal source are automatically controlled when the test frequency and power level are inputted to an automatic test power durability program of the computer 170.

The signal applied to the high power amplifier 112 is amplified to a target power level, for example 30-39 dBm.

The amplified signal is applied to the PDT module 120.

In the PDT module 120, the coupler 121 monitors the power applied to the SAW filter 161, the first and second RF switches 122 and 123 changes the path to monitor the electrical property of the SAW filter 161 using the network analyzer 140. The first and second switches 122 and 123 are controlled by the controller 150. The attenuator 124 attenuates a power level such that the test power level applied to the power meter 130 can be measured by the power meter 130. Also, the attenuator 124 protects the power meter.

The signal outputted from the PDT module 120 is measured by the power meter 130.

The power meter 130 is controlled by the automatic test program, and all measured data are stored in the computer 170.

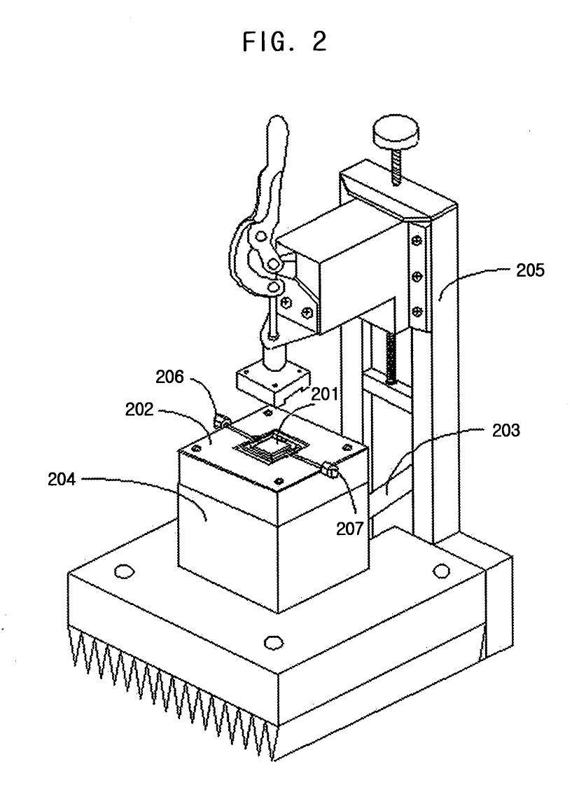

FIG. 2 is a perspective view of the reliability tester of FIG. 1.

Referring to FIG. 2, the reliability tester of the system in accordance with the present invention includes a sample mounting block 202, a heating block 203, a cooling block 204, and a fixing block 205. The sample mounting block 202 mounts the SAW filter 201 thereon. The heating block 203 is formed in a tip shape and is mounted under the SAW filter 201. The heating block 203 maintains the test temperature. The cooling block 204 is formed to surround the heating block 203 and cools the temperature of the SAW filter 201. The fixing block 205 moves the SAW filter 201 vertically. The reliability tester controls the temperature controller 190, which uses a resistance temperature detector (RTD), in the automatic measurement power durability program, so that the temperature of the chip can be controlled up to 300° C.

For example, heat is applied only to the test sample at about 85° C., and room temperature is maintained in the peripheral microstrip line and connectors. Therefore, loss variation according to the temperature is maximally suppressed, so that the test can be reliably carried out. Consequently, a lot of samples can be easily tested.

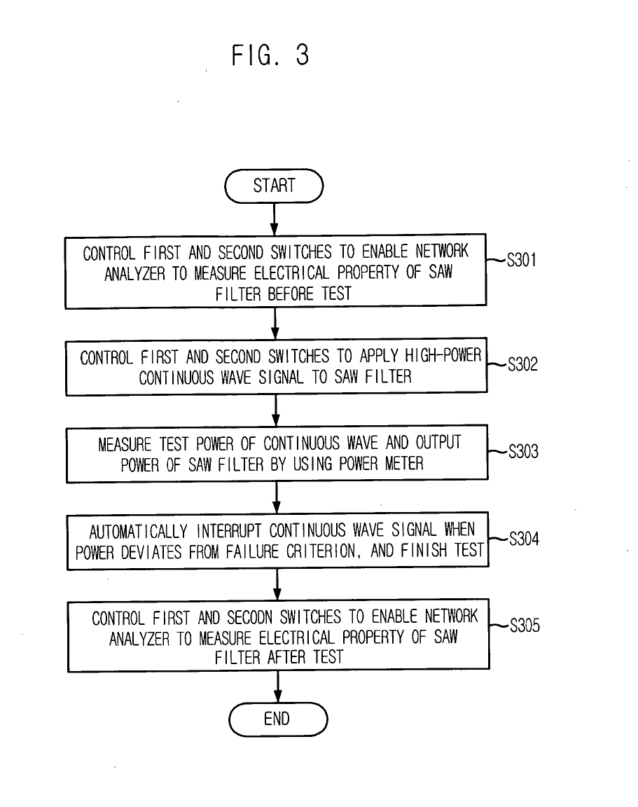

FIG. 3 is a flowchart illustrating a method for testing a power durability of the SAW filter in accordance with an embodiment of the present invention.

Referring to FIG. 3, in step S301, the first and second switches are controlled to enable the network analyzer to measure the electrical property of the SAW filter before the test. In step S302, the first and second switches are controlled to apply the high-power continuous wave signal to the SAW filter.

In step S303, the test power of the continuous wave and the output power of the SAW filter are measured using the power meter. In step S304, when the test power and the output power deviate from the failure criterion, the continuous wave signal from the signal generator is automatically interrupted and the test is finished.

In step 305, after the test is finished, the first and second switches are controlled to enable the network analyzer to measure the electrical properties of the SAW filter.

The method for testing the power durability of the SAW filter will be described below.

The power meter is zeroed and calibrated, and a start frequency and an end frequency of the network analyzer 140 are inputted. Then, the calibration is performed at a first switch port 206 and a second switch port 207 of the reliability tester 160. These operations are controlled on the power durability automatic test program, and the setup of the system is completed.

Then, the test continuous wave and the test power level are inputted on the test program, and the test temperature of the reliability tester 160 is set to 80° C. and is maintained. The first switch port 206 and the second switch port 207 are connected to the port of the power meter 130. Then, an offset value of the power meter 130 is adjusted using the power durability automatic test program, such that the monitored values become equal to each other. In this way, the system is initialized.

After the initialization, the failure criterion of the sample is inputted.

In the failure criterion of the SAW filter, a reference is a time point when an insertion loss in the test frequency increases by 0.5 dB. A test file name is inputted and a power tracking value is set to +0.2 dB. The set value is set to be smaller than 0.5 dB because the failure criterion is 0.5 dB.

The conventional method cannot obtain reliable data contained in an error range of the failure criterion. However, the method in accordance with the present invention can obtain more reliable data.

In the case of the power durability test, when the high power is immediately applied to the SAW filter, the IDT of the SAW filter is damaged. For this reason, a power sweep is set. For example, in the test condition of 35 dBm, the test power is set to gradually increase the test power from 30 dBm to 35 dBm for about 10 minutes.

When the power deviates from the failure criterion (about 0.5 dB), the continuous wave signal from the signal generator 111 is interrupted and the test is finished. The network analyzer 140 measures the electrical property of the SAW filter using the first and second switches 122 and 123. In addition, the first and second switches 122 and 123 are controlled very fast during the test and thus the electrical property of the SAW filter can be monitored. Although this test is intermittent, the SAW filter is not intermittent in terms of heat. Therefore, it has no relation to the abrupt breakdown.

After the test is finished, the test date, the test temperature of the SAW filter measured by the thermal meter 180, the test power level, the test frequency, the output power, the test time, and the electrical characteristic values before and after the test are stored as data. The data are applied to the reliability test model (Eyring's model) and floated on the probability paper. Therefore, the life span can be predicted.

As described above, since the method in accordance with the present invention tests the power durability using the automatic measurement power durability program, it can predict the life span conveniently and reliably.

In accordance with the present invention, the reliability test system can correctly control the test temperature using the RTD sensor. Thus, compared with the prior art, the life span of the RF passive parts such as the SAW filter and the Duplexer can be correctly predicted. Since the automatic measurement program is used, it is convenient. In addition, since the correct measurement and control are possible, the power durability can be correctly tested.

Moreover, by applying the reliability model to the automatic measurement program, the life span can be predicted with various test conditions and measured data. Further, the present invention can be applied to the accelerated life test by replacing the high power parts of the power amplifier and other PDT modules in the passive parts used in the base station.

The above-described methods in accordance with the present invention can be stored in computer-readable recording media. The computer-readable recording media may include CDROM, RAM, ROM, floppy disk, hard disk, optical magnetic disk, and so on. Since these procedures can be easily carried out by those skilled in the art, a detailed description thereof will be omitted.

The present application contains subject matter related to Korean patent application No. [symbol] , filed in the Korean Intellectual Property Office on [symbol] , [symbol] , the entire contents of which is incorporated herein by reference.

While the present invention has been described with respect to certain preferred embodiments, it will be apparent to those skilled in the art that various changes and modifications may be made without departing from the scope of the invention as defined in the following claims.

What is claimed is:

1. A system for testing a power durability of a surface acoustic wave (SAW) filter, comprising:
a signal generator for generating a continuous wave of an oscillator;
a high power amplifier for amplifying a signal applied from the signal generator into a target power level;
a power durability tester (PDT) for receiving the amplified signal from the high power amplifier and monitoring a power applied to a SAW filter, and setting a path for monitoring an electrical property through a network analyzer;
a power meter for measuring an output signal of the PDT;
a controller for changing a path to monitor an electric property of the PDT;
the network analyzer for analyzing an electrical property of the SAW filter;
a reliability tester for applying a test temperature to the SAW filter and maintaining the applied test temperature;
a thermal meter for measuring a temperature of the SAW filter;
a temperature controller for controlling a test temperature applied to the reliability tester; and
a computer for controlling the signal generator, the power meter, the network analyzer, the controller, the temperature controller, and the thermal meter.

2. The system as recited in claim 1, wherein the PDT includes:
a coupler for monitoring the power applied to the SAW filter;
a switch for changing the path to monitor the electrical property of the SAW filter using the network analyzer; and
an attenuator for attenuating the test power level such that the test power level applied to the power meter is measured in the power meter, and for protecting the power meter.

3. The system as recited in claim 1, wherein the reliability tester includes:
sample mounting means for mounting the SAW filter thereon;
heating means, formed in a tip shape and mounted under the SAW filter, for maintaining the test temperature;
cooling means, formed to surround the heating means, for cooling the temperature of the SAW filter, the cooling means and the heating means being separated from each other; and
a fixing means for moving the SAW filter vertically.

4. The system as recited in claim 1, wherein the computer is controlled by a program for automatically testing the power durability.

5. A method for testing a power durability of a SAW filter, comprising the steps of:
controlling first and second switches to measure an electrical property of the SAW filter using a network analyzer before test;
controlling the first and second switches to applying a high-power continuous wave signal to the SAW filter;
measuring a test power of the continuous wave and an output power of the SAW filter using a power meter;
when the test power and the output power deviate from a failure criterion, automatically interrupting the continuous wave signal from the signal generator and finishing the test; and
measuring the electrical properties of the SAW filter after the test through the network analyzer by using the first and second switches.
